(19) United States
(12) Patent Application Publication
(10) Pub. No.: US 2009/0294961 A1
(43) Pub. Date: Dec. 3, 2009

(54) SEMICONDUCTOR DEVICE

(75) Inventors: Thorsten Meyer, Regensburg (DE); Recai Sezi, Rottenbach (DE); Markus Brunnbauer, Lappersdorf (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies AG, Neubiberg, DE (US)

(21) Appl. No.: 12/131,541

(22) Filed: Jun. 2, 2008

(51) Int. Cl. H01L 23/488; H01L 21/44

(52) U.S. Cl. 257/738; 438/613; 257/E21.476; 257/E23.023

(57) ABSTRACT

A semiconductor device includes a semiconductor chip and a metal layer electrically coupled to the semiconductor chip. The semiconductor device includes an array of solder balls coupled to the metal layer and a front side protect material directly contacting the metal layer and laterally surrounding a portion of at least a plurality of solder balls. The front side protect material is configured to become fluid during solder reflow.

### BACKGROUND

Bare die or wafer level packages include a semiconductor die and a redistribution layer (RDL) or metal layer for routing signals from the internal circuitry of the semiconductor die to external solder balls. The wafer level package is coupled to a printed circuit board (PCB) by soldering the solder balls to the printed circuit board to provide a product. Over the lifetime of the product, the product may be subjected to thermal cycling, such as thermal cycling between −40° C. and 125° C. Typically, the coefficient of thermal expansion (CTE) between the semiconductor substrate and the printed circuit board varies. The variation in the coefficient of thermal expansion results in the solder balls experiencing shear forces in response to thermal cycling. After repeated thermal cycles, the shear forces may crack the solder balls leading to a failure of the product.

For these and other reasons, there is a need for the present invention.

### SUMMARY

One embodiment provides a semiconductor device. The semiconductor device includes a semiconductor chip and a metal layer electrically coupled to the semiconductor chip. The semiconductor device includes an array of solder balls coupled to the metal layer and a front side protect material directly contacting the metal layer and laterally surrounding a portion of at least a plurality of solder balls. The front side protect material is configured to become fluid during solder reflow.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a cross-sectional view of one embodiment of an integrated circuit.

FIG. 2 illustrates a cross-sectional view of another embodiment of an integrated circuit.

FIG. 3 illustrates a cross-sectional view of one embodiment of a preprocessed wafer.

FIG. 4 illustrates a cross-sectional view of one embodiment of the preprocessed wafer and a dielectric material layer.

FIG. 5 illustrates a cross-sectional view of one embodiment of the preprocessed wafer, the dielectric material layer, a conductive material layer, a seed layer, and a mask material layer.

FIG. 6 illustrates a cross-sectional view of one embodiment of the preprocessed wafer, the dielectric material layer, the conductive material layer, the seed layer, a redistribution line, and the mask material layer.

FIG. 7 illustrates a cross-sectional view of one embodiment of the preprocessed wafer, the dielectric material layer, the conductive material layer, and the redistribution line.

FIG. 8 illustrates a cross-sectional view of one embodiment of the preprocessed wafer, the dielectric material layer, the conductive material layer, the redistribution line, and a front side protect material layer.

FIG. 9 illustrates a cross-sectional view of one embodiment of the preprocessed wafer, the dielectric material layer, the conductive material layer, the redistribution line, and a non-structured resist material layer.

FIG. 10 illustrates a cross-sectional view of one embodiment of the preprocessed wafer, the dielectric material layer, the conductive material layer, the redistribution line, the non-structured resist material layer, and a front side protect material layer.

FIG. 11 illustrates a cross-sectional view of one embodiment of the preprocessed wafer, the dielectric material layer, the conductive material layer, the redistribution line, the non-structured resist material layer, and the front side protect material layer after removing a portion of the non-structured resist material layer.

FIG. 12 illustrates a cross-sectional view of one embodiment of the preprocessed wafer, the dielectric material layer, the conductive material layer, the redistribution line, and the non-structured resist material layer after removing a portion of the non-structured resist material layer.

FIG. 13 illustrates a cross-sectional view of one embodiment of the preprocessed wafer, the dielectric material layer, the conductive material layer, the redistribution line, the non-structured resist material layer, and a front side protect material layer.

FIG. 14 illustrates a cross-sectional view of one embodiment of the preprocessed wafer, the dielectric material layer, the conductive material layer, the redistribution line, the front side protect material layer, a flux material layer, and a solder ball.

FIG. 15 illustrates a cross-sectional view of another embodiment of an integrated circuit.

FIG. 16 illustrates a cross-sectional view of one embodiment of a preprocessed wafer.

FIG. 17 illustrates a cross-sectional view of one embodiment of the preprocessed wafer and a front side protect material layer.

FIG. 18 illustrates a cross-sectional view of one embodiment of the preprocessed wafer, the front side protect material layer, a flux material layer, and a solder ball.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

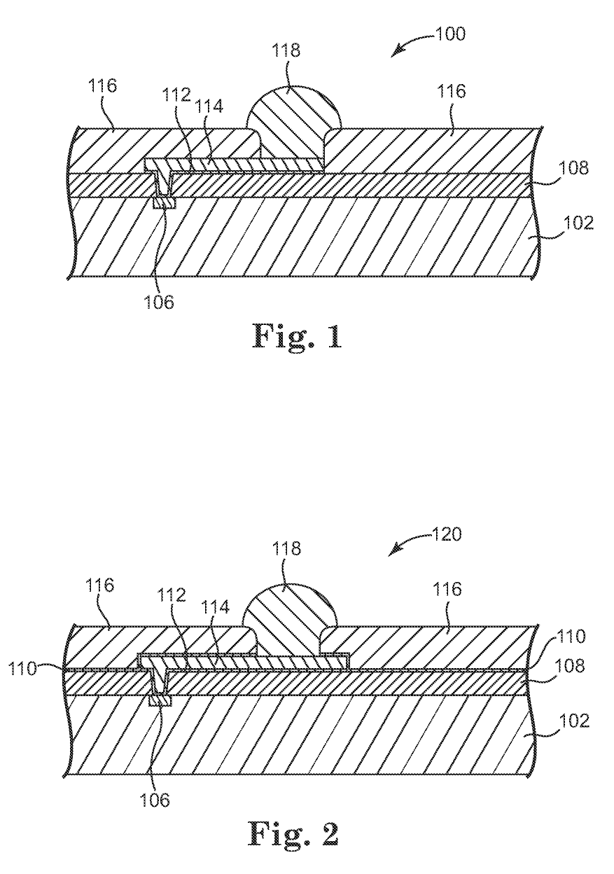

FIG. 1 illustrates a cross-sectional view of one embodiment of an integrated circuit 100. Integrated circuit 100 is fabricated using a wafer level packaging process. Integrated circuit 100 includes a semiconductor chip or die 102 including circuitry (not shown) and at least a contact pad 106. Integrated circuit 100 includes a dielectric material layer 108, a conductive material layer 112, a redistribution line 114 of a redistribution layer (RDL), a front side protect (FSP) material layer 116, and at least a solder ball 118. Integrated circuit 100 illustrates only a single contact pad 106, redistribution line 114, and solder ball 118 for simplicity. In other embodiments, however, integrated circuit 100 includes any suitable number of contact pads 106, redistribution lines 114, and solder balls 118 to provide a wafer level ball grid array (WLB) package.

Contact pad 106 is electrically coupled to solder ball 118 through conductive material layer 112 and redistribution line 114. Front side protect material layer 116 directly contacts and supports solder ball 118 at the interface between solder ball 118 and redistribution line 114. In one embodiment, front side protect material layer 116 is a photo-structurable, b-stageable material used in place of the typical solder stop material. A b-stageable material is a material having an intermediate stage in which the material swells when in contact with certain liquids and softens when heated, but may not entirely dissolve or fuse. Front side protect material layer 116 includes an epoxy material, a thermoset material, a thermoplastic material, or another suitable material.

Front side protect material layer 116 softens and becomes fluid during the reflow process in which deposited solder material softens and reflows to provide solder ball 118. Due to the b-stageable material becoming fluid during the reflow process, the b-stageable material makes direct contact to the solder material during the reflow process and maintains the direct contact once the solder material and the b-stageable material solidify. In this way, front side protect material 116 supports the weakest point of the solder ball 118 and absorbs some of the stress solder ball 118 experiences during thermal cycling. Therefore, solder ball 118 is less likely to fail in response to thermal cycling.

In one embodiment, integrated circuit 100 includes a fan-in wafer level package. In another embodiment, integrated circuit 100 includes a fan-out wafer level package. Semiconductor chip 102 includes a silicon substrate or another suitable substrate. The top of semiconductor chip 102 contacts the bottom of dielectric material layer 108. Dielectric material layer 108 includes a polyimide, an epoxy-based material, or another suitable dielectric material. The top of dielectric material layer 108 contacts a portion of the bottom of conductive material layer 112 and a portion of the bottom of front side protect material layer 116.

Contact pad 106 includes Al or another suitable contact material. The top of contact pad 106 contacts a portion of the bottom of conductive material layer 112. Conductive material layer 112 includes TiW or another suitable conductive material. The top of conductive material layer 112 contacts the bottom of redistribution line 114. Redistribution line 114 includes Cu or another suitable conductive material. The top of redistribution line 114 contacts solder ball 118 and a portion of the bottom of front side protect material layer 116. Front side protect material layer 116 laterally surrounds at least 20% of solder ball 118, such as 20% to 50% of solder ball 118.

FIG. 2 illustrates a cross-sectional view of another embodiment of an integrated circuit 120. Integrated circuit 120 is similar to integrated circuit 100 previously described and illustrated with reference to FIG. 1, except integrated circuit 120 includes a non-structured resist material layer 110. The bottom of non-structured resist material layer 110 contacts the top of a portion of dielectric material layer 108, the sidewalls of conductive material layer 112, and a portion of the top and sidewalls of redistribution line 114. The top of non-structured resist material layer 110 contacts the bottom of front side protect material layer 116. The thickness of non-structured resist material layer 110 is less than the thickness of front side protect material layer 116. Non-structured resist material layer 110 includes a parylene, an organic protection material, or another suitable material.

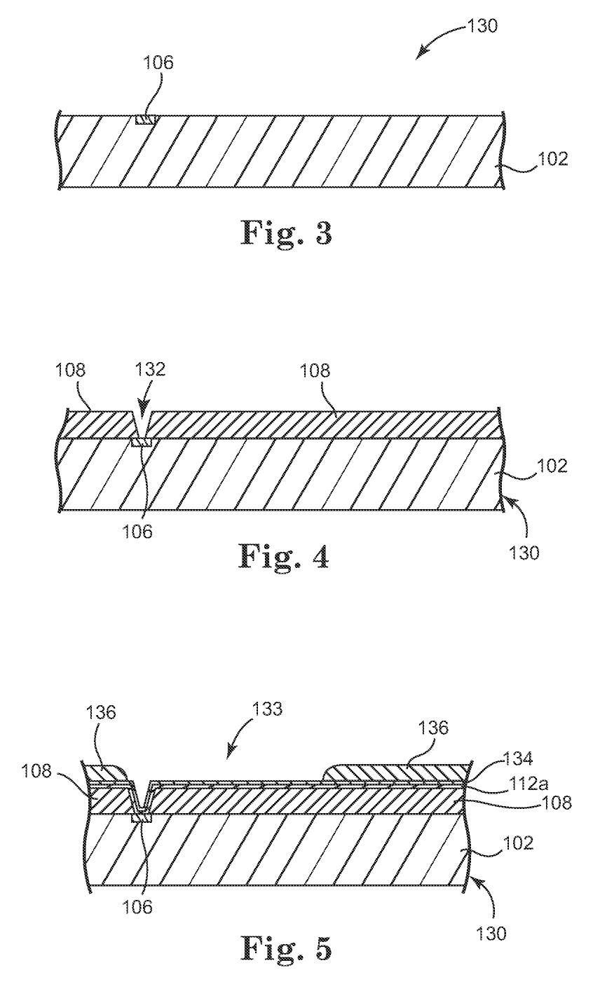

The following FIGS. 3-13 illustrate embodiments for fabricating an integrated circuit including a WLB package, such as integrated circuit 100 previously described and illustrated with reference to FIG. 1 or integrated circuit 120 previously described and illustrated with reference to FIG. 2.

FIG. 3 illustrates a cross-sectional view of one embodiment of a preprocessed wafer 130. Preprocessed wafer 130 includes a substrate 102 and a contact pad 106. Contact pad 106 is electrically coupled to circuitry (not shown) within substrate 102. Substrate 102 include silicon or another suitable material. Contact pad 106 includes aluminum or another suitable material.

FIG. 4 illustrates a cross-sectional view of one embodiment of preprocessed wafer 130 and a dielectric material layer 108. A dielectric material, such as a polyimide, an epoxy-based material, or another suitable dielectric material is deposited over preprocessed wafer 130. The dielectric material layer is deposited using a spin-on deposition or another suitable deposition technique (e.g., printing). In one embodiment, the dielectric material is photo-structurable and the dielectric material layer is exposed and developed to provide an opening 132 exposing at least a portion of contact pad 106 and to provide dielectric material layer 108. Opening 132 is patterned using a photolithography process or another suitable process if it is not structured during the application process.

FIG. 5 illustrates a cross-sectional view of one embodiment of preprocessed wafer 130, dielectric material layer 108, a conductive material layer 112a, a seed layer 134, and a mask layer 136. A conductive material, such as TiW or another suitable conductive material is conformally deposited over exposed portions of dielectric material layer 108 and contact pad 106 to provide conductive material layer 112a. Conductive material layer 112a is deposited using a sputter deposition or another suitable deposition technique. In one embodiment, conductive material layer 112a is deposited to a thickness of approximately 50 nm or another suitable thickness.

A seed material, such as Cu or another suitable seed material is conformally deposited over conductive material layer 112a to provide seed layer 134. Seed layer 134 is deposited using a sputter deposition or another suitable deposition technique. In one embodiment, seed layer 134 is deposited to a thickness of approximately 150 nm or another suitable thickness. In one embodiment, conductive material layer 112a and seed layer 134 are collectively referred to as a seed layer.

A mask material, such as photoresist or another suitable mask material is deposited over seed layer 134 to provide a mask material layer. The mask material layer is patterned and a portion is etched or removed to provide opening 133 exposing a portion of seed layer 134 and to provide mask material layer 136.

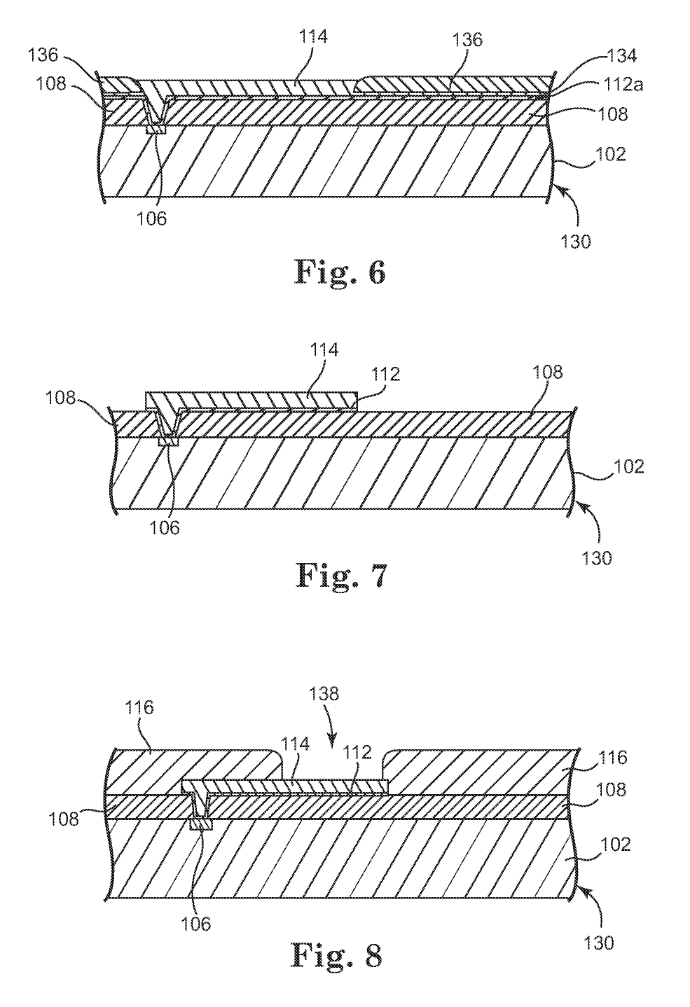

FIG. 6 illustrates a cross-sectional view of one embodiment of preprocessed wafer 130, dielectric material layer 108, conductive material layer 112a, seed layer 134, mask material layer 136, and a redistribution line 114. In one embodiment, an electroplating process is used to deposit Cu or another suitable metal on exposed portions of seed layer 134 to provide redistribution line 114. In one embodiment, the Cu is electroplated to a thickness of approximately 6 μm or another suitable thickness.

FIG. 7 illustrates a cross-sectional view of one embodiment of preprocessed wafer 130, dielectric material layer 108, conductive material layer 112, and redistribution line 114. Mask material layer 136 is removed to expose portions of seed layer 134. The exposed portions of seed layer 134 are etched to expose portions of conductive material layer 112a. The exposed portions of conductive material layer 112a are etched to expose dielectric material layer 108 and to provide conductive material layer 112.

FIG. 8 illustrates a cross-sectional view of one embodiment of preprocessed wafer 130, dielectric material layer 108, conductive material layer 112, redistribution line 114, and a front side protect material layer 116. In one embodiment, a photo-structurable, b-stageable material is deposited over exposed portions of preprocessed wafer 130, dielectric material layer 108, and redistribution line 114 to provide a b-stageable material layer. The b-stageable material layer includes an epoxy material, a thermoset material, a thermoplastic material, or another suitable material. The b-stageable material layer is deposited using a spin-on deposition or another suitable deposition technique (e.g., printing).

If not patterned during the application process, the b-stageable material layer is then patterned and a portion is etched, developed, or removed to provide opening 138 exposing a portion of redistribution line 114 and to provide front side protect material layer 116. The b-stageable material layer is patterned using photolithography or another suitable technique if it is not structured during the application process. In one embodiment, front side protect material layer 116 is then pre-cured. In one embodiment, front side protect material layer 116 replaces the solder stop material layer typically used for integrated circuits including WLB packages.

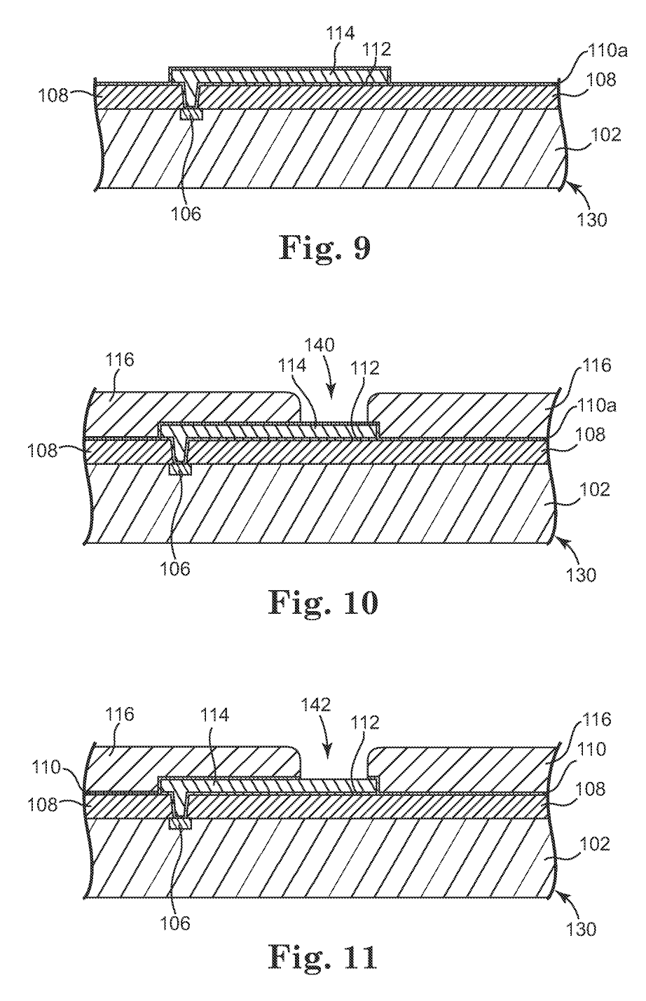

The following FIGS. 9-11 illustrate another embodiment for fabricating an integrated circuit including a WLB package, such as integrated circuit 120 previously described and illustrated with reference to FIG. 2. To begin, the process previously described and illustrated with reference to FIGS. 3-7 is performed.

FIG. 9 illustrates a cross-sectional view of one embodiment of preprocessed wafer 130, dielectric material layer 108, conductive material layer 112, redistribution line 114, and a non-structured resist material layer 110a. A non-structured resist material, such as a parylene, an organic protection material, or another suitable non-structured resist material is deposited over exposed portions of dielectric material layer 108, conductive material layer 112, and redistribution line 114 to provide non-structured resist material layer 110a. Non-structured resist material layer 110a is deposited by printing or by using a spin-on deposition, a vapor phase deposition, or another suitable deposition technique.

FIG. 10 illustrates a cross-sectional view of one embodiment of preprocessed wafer 130, dielectric material layer 108, conductive material layer 112, redistribution line 114, non-structured resist material layer 110a, and a front side protect material layer 116. In one embodiment, a photo-structurable, b-stageable material is deposited over non-structured resist material layer 110a to provide a b-stageable material layer. The b-stageable material layer includes an epoxy material, a thermoset material, a thermoplastic material, or another suitable material. The b-stageable material layer is deposited using a spin-on deposition or another suitable deposition technique (e.g., printing).

If the b-stageable material is not patterned during its application, the b-stageable material layer is then patterned and a portion is etched, developed, or removed to provide opening 140 exposing a portion of non-structured resist material layer 110a and to provide front side protect material layer 116. The b-stageable material layer is patterned using photolithography or another suitable technique if it is not structured during the application process. In one embodiment, front side protect material layer 116 is then pre-cured.

FIG. 11 illustrates a cross-sectional view of one embodiment of preprocessed wafer 130, dielectric material layer 108, conductive material layer 112, redistribution line 114, non-structured resist material layer 110, and front side protect material layer 116 after removing a portion of non-structured resist material layer 110a. The exposed portion of non-structured resist material layer 110a is removed to expose a portion of redistribution line 114 as indicated at 142 and to provide non-structured resist material layer 110. The exposed portion of non-structured resist material layer 110a is removed by plasma etching, chemical etching, physical removal, or by another suitable technique. Non-structured resist material layer 110 and front side protect material layer 116 replace the solder stop material layer typically used for integrated circuits including WLB packages.

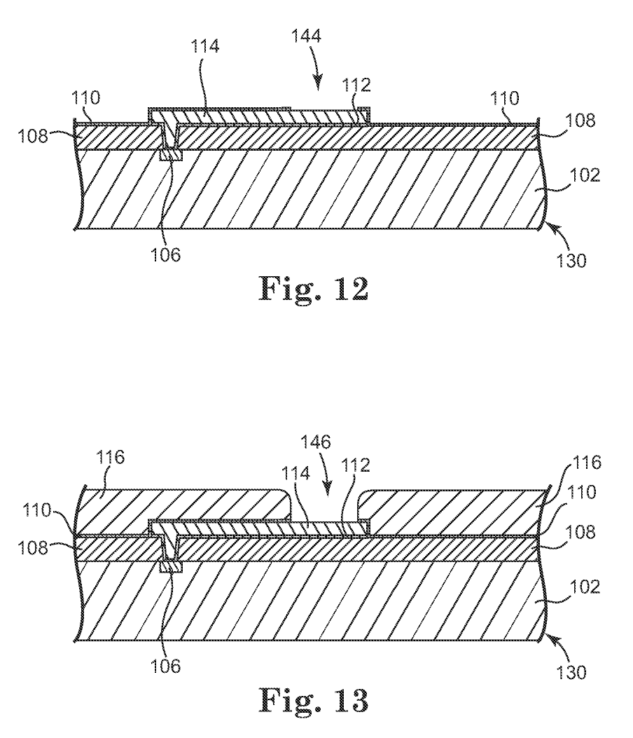

The following FIGS. 12 and 13 illustrate another embodiment for fabricating an integrated circuit including a WLB package, such as integrated circuit 120 previously described and illustrated with reference to FIG. 2. To begin, the process previously described and illustrated with reference to FIGS. 3-7 and 9 is performed.

FIG. 12 illustrates a cross-sectional view of one embodiment of preprocessed wafer 130, dielectric material layer 108, conductive material layer 112, redistribution line 114, and non-structured resist material layer 110 after removing a portion of non-structured resist material layer 110a. Non-structured resist material layer 110a is patterned and a portion of non-structured resist material layer 110a is removed to expose a portion of redistribution line 114 as indicated at 144 and to provide non-structured resist material layer 110. Non-structured resist material layer 110a is patterned using photolithography or another suitable technique. The portion of non-structured resist material layer 110a is removed by plasma etching, chemical etching, physical removal, or by another suitable technique.

FIG. 13 illustrates a cross-sectional view of one embodiment of preprocessed wafer 130, dielectric material layer 108, conductive material layer 112, redistribution line 114, non-structured resist material layer 110, and a front side protect material layer 116. A photo-structurable, b-stageable material is deposited over non structured resist material layer 110 and exposed portions of redistribution line 114 to provide a b-stageable material layer. The b-stageable material layer includes an epoxy material, a thermoset material, a thermoplastic material, or another suitable material. The b-stageable material layer is deposited using a spin-on deposition or another suitable deposition technique (e.g., printing).

If the b-stageable material is not patterned during its application, the b-stageable material layer is then patterned and a portion is etched, developed, or removed to provide opening 146 exposing a portion of redistribution line 114 and to provide front side protect material layer 116. The b-stageable material layer is patterned using photolithography or another suitable technique if it is not structured during the application process. In one embodiment, front side protect material layer 116 is then pre-cured. In one embodiment, front side protect material layer 116 and non-structured resist material layer 110 replace the solder stop material layer typically used for integrated circuits including WLB packages.

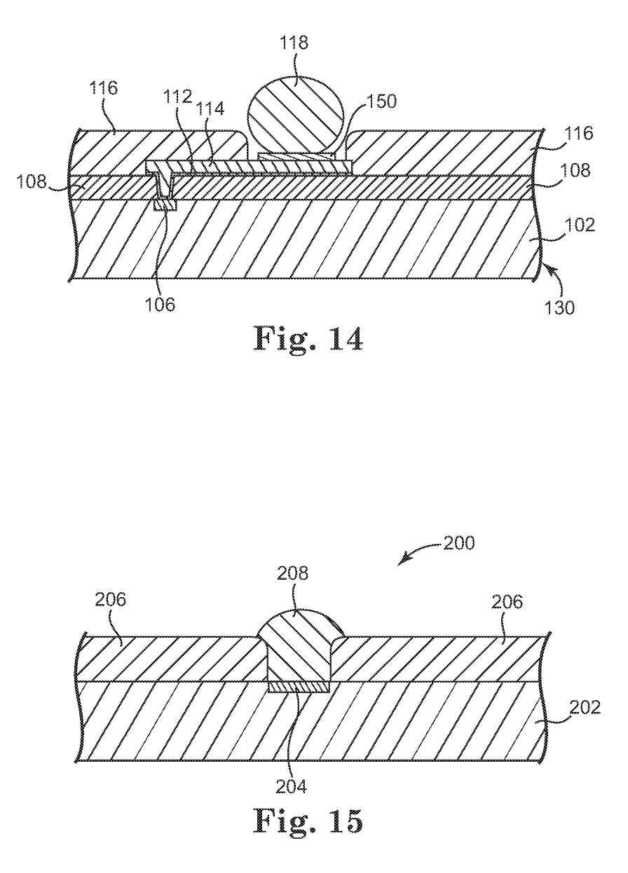

FIG. 14 illustrates a cross-sectional view of one embodiment of preprocessed wafer 130, dielectric material layer 108, conductive material layer 112, redistribution line 112, front side protect material layer 116, a flux material layer 150, and a solder ball 118. A flux material is applied to exposed portions of redistribution line 114 to provide flux material layer 150. Solder material or a solder ball 118 is applied on flux material layer 150. The solder material or solder ball is then reflowed. During the reflow process, front side protect material layer 116 also softens and becomes fluid such that front side protect material layer 116 directly contacts the solder ball. After the reflow process, the solder ball and front side protect material solidify to provide integrated circuit 100 previously described and illustrated with reference to FIG. 1. A similar process is used to complete the fabrication of integrated circuit 120 previously described and illustrated with reference to FIG. 2.

FIG. 15 illustrates a cross-sectional view of another embodiment of an integrated circuit 200. Integrated circuit 200 includes a semiconductor chip or die 202 including circuitry (not shown) and at least a contact pad 204. Integrated circuit 200 includes a front side protect material layer 206 and at least a solder ball 208. Integrated circuit 200 illustrates only a single contact pad 204 and solder ball 208 for simplicity. In other embodiments, however, integrated circuit 200 includes any suitable number of contact pads 204 and solder balls 208 to provide a wafer level ball grid array (WLB) package.

Semiconductor chip 202 includes a silicon substrate or another suitable substrate. Contact pad 204 includes Al or another suitable contact material. Contact pad 204 is electrically coupled to solder ball 208. The top of semiconductor chip 202 contacts the bottom of front side protect material layer 206. Front side protect material layer 206 laterally surrounds at least 20% of solder ball 208, such as 20% to 50% of solder ball 208. Front side protect material layer 206 directly contacts and supports solder ball 208 at the interface between solder ball 208 and contact pad 204. In one embodiment, front side protect material layer 206 is a photo-structurable, b-stageable material used in place of the typical solder stop material. Front side protect material layer 206 includes an epoxy material, a thermoset material, a thermoplastic material, or another suitable material.

Front side protect material layer 206 softens and becomes fluid during the reflow process in which deposited solder material softens and reflows to provide solder ball 208. Due to the b-stageable material becoming fluid during the reflow process, the b-stageable material makes direct contact to the solder material during the reflow process and maintains the direct contact once the solder material and the b-stageable material solidify. In this way, front side protect material 206 supports the weakest point of the solder ball 208 and absorbs some of the stress solder ball 208 experiences during thermal cycling. Therefore, solder ball 208 is less likely to fail in response to thermal cycling.

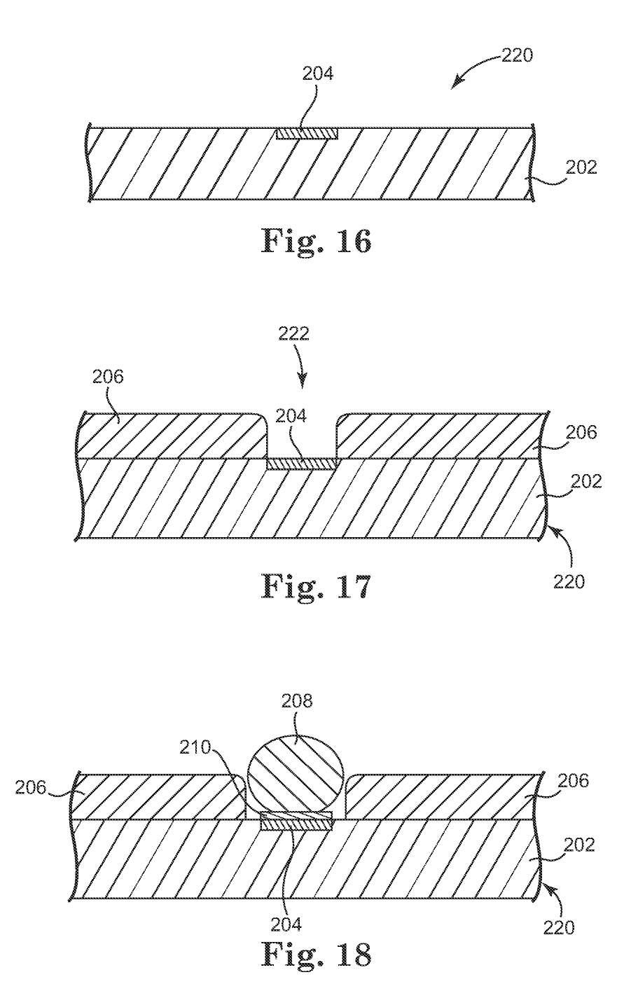

The following FIGS. 16-18 illustrate embodiments for fabricating an integrated circuit including a WLB package, such as integrated circuit 200 previously described and illustrated with reference to FIG. 15.

FIG. 16 illustrates a cross-sectional view of one embodiment of a preprocessed wafer 220. Preprocessed wafer 220 includes a substrate 202 and a contact pad 204. Contact pad 204 is electrically coupled to circuitry (not shown) within substrate 202. Substrate 202 include silicon or another suitable material. Contact pad 204 includes aluminum or another suitable material.

FIG. 17 illustrates a cross-sectional view of one embodiment of preprocessed wafer 220 and a front side protect material layer 206. In one embodiment, a photo-structurable, b-stageable material is deposited over preprocessed wafer 220 to provide a b-stageable material layer. The b-stageable material layer includes an epoxy material, a thermoset material, a thermoplastic material, or another suitable material. The b-stageable material layer is deposited using a spin-on deposition or another suitable deposition technique (e.g., printing).

If not patterned during the application process, the b-stageable material layer is then patterned and a portion is etched, developed, or removed to provide opening 222 exposing at least a portion of contact pad 204 and to provide front side protect material layer 206. The b-stageable material layer is patterned using photolithography or another suitable technique if it is not structured during the application process. In one embodiment, front side protect material layer 206 is then pre-cured. In one embodiment, front side protect material layer 206 replaces the solder stop material layer typically used for integrated circuits including WLB packages.

FIG. 18 illustrates a cross-sectional view of one embodiment of preprocessed wafer 220, front side protect material layer 206, a flux material layer 210, and a solder ball 208. A flux material is applied to exposed portions of contact pad 204 to provide flux material layer 210. Solder material or a solder ball 208 is applied on flux material layer 210. The solder material or solder ball is then reflowed. During the reflow process, front side protect material layer 206 also softens and becomes fluid such that front side protect material layer 206 directly contacts the solder ball. After the reflow process, the solder ball and front side protect material solidify to provide integrated circuit 200 previously described and illustrated with reference to FIG. 15.

Embodiments provide integrated circuits including WLB packages. The WLB packages use front side protect material in place of the solder stop material typically used. In addition, embodiments provide integrated circuits including a non-structured resist material layer between the front side protect material and the redistribution lines and dielectric material. The front side protect material provides additional support to the solder balls to prevent the solder balls from failing due to shear forces applied to the solder balls during thermal cycling.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device comprising:
a semiconductor chip;
a metal layer electrically coupled to the semiconductor chip;
an array of solder balls coupled to the metal layer; and
a front side protect material directly contacting the metal layer and laterally surrounding a portion of at least a plurality of solder balls, the front side protect material configured to become fluid during solder reflow.

2. The semiconductor device of claim 1, wherein the front side protect material laterally surrounds at least 20% of each solder ball.

3. The semiconductor device of claim 1, wherein the front side protect material directly contacts each solder ball.

4. The semiconductor device of claim 1, wherein the front side protect material comprises b-stageable material.

5. The semiconductor device of claim 1, wherein the front side protect material comprises one of an epoxy material, a thermoset material, and a thermoplastic material.

6. The semiconductor device of claim 1, wherein the front side protect material comprises photo-structurable material.

7. A semiconductor device package comprising:
a semiconductor die;
at least one redistribution line electrically coupled to the semiconductor die;
at least one solder ball electrically coupled to the at least one redistribution line; and
means for supporting the solder ball at an interface of the at least one solder ball and the at least one redistribution line.

8. The semiconductor device package of claim 7, wherein the means comprises front side protect material configured to become fluid during solder reflow.

9. The semiconductor device package of claim 8, wherein the front side protect material laterally surrounds at least 20% of the at least one solder ball.

10. The semiconductor device package of claim 8, wherein the front side protect material comprises b-stageable material.

11. The semiconductor device package of claim 8, wherein the front side protect material comprises one of an epoxy material, a thermoset material, and a thermoplastic material.

12. An integrated circuit comprising:
a semiconductor die;
at least one redistribution line electrically coupled to the semiconductor die;
at least one solder ball electrically coupled to the at least one redistribution line;
a resist material directly contacting the at least one redistribution line; and
a front side protect material directly contacting the resist material and laterally surrounding a portion of the at least one solder ball, the front side protect material configured to become fluid during solder reflow.

13. The integrated circuit of claim 12, wherein the front side protect material laterally surrounds at least 20% of the at least one solder ball.

14. The integrated circuit of claim 12, wherein the front side protect material directly contacts the at least one solder ball.

15. The integrated circuit of claim 12, wherein the front side protect material comprises a photo-structurable, b-stageable material.

16. The integrated circuit of claim 12, wherein the front side protect material comprises one of an epoxy material, a thermoset material, and a thermoplastic material.

17. The integrated circuit of claim 12, wherein the resist material comprises one of parylene and an organic protection material.

18. A method for fabricating a semiconductor device, the method comprising:
providing a preprocessed wafer;
applying a front side protect material layer over the preprocessed wafer;
applying solder material to the preprocessed wafer; and
softening the solder material and the front side protect material until an array of solder balls is formed.

19. The method of claim 18, further comprising:
removing portions of the front side protect material layer to expose portions of the preprocessed wafer prior to applying the solder material.

20. The method of claim 18, further comprising:
fabricating at least one metal layer over the preprocessed wafer prior to applying the front side protect material layer.

21. The method of claim 18, wherein softening the solder material and the front side protect material comprises softening the solder material and the front side protect material until the array of solder balls is formed such that the front side protect material laterally surrounds at least 20% of each solder ball.

22. The method of claim 18, wherein softening the solder material and the front side protect material comprises softening the solder material and the front side protect material until the array of solder balls is formed such that the front side protect material directly contacts each solder ball.

23. The method of claim 18, wherein applying the front side protect material comprises applying a b-stageable material.

24. The method of claim 18, wherein applying the front side protect material comprises applying one of an epoxy material, a thermoset material, and a thermoplastic material.

25. A method for fabricating an integrated circuit, the method comprising:
providing a preprocessed wafer;
fabricating at least one redistribution layer coupled to the preprocessed wafer;
applying a resist material layer over the at least one redistribution layer;
applying a front side protect material layer over the resist material layer;
applying solder material to the at least one redistribution layer; and
softening the solder material and the front side protect material until an array of solder balls is formed.
